(19) United States
(12) Patent Application Publication
(10) Pub. No.: US 2007/0217457 A1
(43) Pub. Date: Sep. 20, 2007

(54) Optically Pumped Semiconductor Devices for the Generation of Radiation, Their Production as Well as Methods for the Strain Compensation in the Layer Successions used Within

(76) Inventors: Wolfgang Stolz, Marburg (DE); Stephan Lutgen, Regensburg (DE)

Correspondence Address: CLARK & BRODY, 1090 VERMONT AVENUE, NW, SUITE 250, WASHINGTON, DC, 20005, US

(21) Appl. No.: 10/580,653

(22) PCT Filed: Nov. 25, 2004
(86) PCT No.: PCT/DE04/02624

§ 371 Date: Mar. 30, 2007

(30) Foreign Application Priority Data
Nov. 25, 2003 (DE) 103 55 357.6

(51) Int. Cl. H01S 5/00

(52) U.S. Cl. 372/43.01

(57) ABSTRACT

A new method for the production of strain-compensating semiconductor layers is suggested, as well as its use for the production of strained-controlled semiconductor layer systems and the production of optically pumped semiconductor devices for the production of radiation, preferably long-wave radiation.

The invention at hand describes the production and realization of long-wave MILOS disk lasers (Monolithic Integrated Lateral Optical Pumped Semiconductor=MILOS), externally pumped by barrier/quantum film means and electrically pumped disk lasers by means of epitaxy (MBE, MOMBE, GSMBE, MOVPE) as well as a procedure for the compensation of strains of the layers used within.

### STATE OF THE ART

The optically pumped semiconductor laser structures, which are discussed here, consist mainly of a coupling layer, an active area formed by quantum films which are arranged in such a way that they feature an optimum overlapping to the light field of the pump laser and an epitaxial (lambda/4) multiple layer reflector (Distributed Bragg-Reflector, DBR) which reflects the light issued by the quantum films back and therefore represents the highly reflective end reflector within the laser resonator.

For the layer structures used, as everyone knows, the implementation of strain-compensating layers becomes more important with an increasing wavelength of the emission and, thus, increasing strain. This compressive strain must be compensated by tensile-strained layers, within the layer successions discussed here, which must contain active quantum film packages for an efficient absorption of the pump light in the range from, e.g., 5 to 25 or more.

For the realization of long-wave disk lasers >1,000 nm, compressively strained InGaAs quantum films with In-concentrations of typically >18% and layer thicknesses with typically <10 nm are required for the light production. These can be produced, e.g., at MOVPE growth temperatures of >600° C., with good quality only for wavelengths up to approx. 1,000 nm, since relaxation of the strained individual layers starts above the critical layer thickness.

A further increase of the critical layer thickness can be achieved by a lower addition of energy, i.e., for instance, by a lower growth temperature T<600° C.

### Disadvantage in the State of the Art

The AsH3- and PH3-group-V gas sources used until now in the MOVPE feature, at this low addition of energy, i.e., for instance, in the form of a growth temperature of T<600° C., very bad decomposition characteristics.

Due to the low decomposition efficiency of AsH3- and PH3-group-V gas sources in the MOVPE at these low temperatures the use of alternative sources for As and P is required.

### AIM OF THE INVENTION

It is, hence, the task of the present invention to provide a method for the compensation of strains in the layer successions of optically pumped semiconductor devices for the production of radiation, particularly long-wave radiation using the aforementioned epitaxy methods.

With the layer successions produced by this method, qualitatively more sophisticated optically pumped semiconductor devices, and, in general, strain-controlled semiconductor multiple layer structures can be produced.

### Achievement of the Aim

Surprisingly, it was found that in epitaxy methods with a low addition of energy, e.g. with MOVPE and at low temperatures, i.e. at T<600° C., that an advantageous strain compensation is reached when layers—within the layers to be compensated in their individual or common strain—e.g. from Ga(PAs) or/and Ga(Nas) or/and (GaIn)(NAs), and apart from the known N sources (hydrazines such as 1,1 dimethylhydrazine ((CH3)2N—NH2, UDMHy) or also tertiarybutylhydrazine (t-C4H9HN—NH2)) and known Sb sources, by using TBAs and/or TBP sources (tertiary butylarsine, i.e. (t-C4H9AsH2) or tertiarybutylphosphine (t-C4H9PH2, TBP)) or corresponding arsenic alkyl compounds and alkylphosphine compounds, are deposited during the epitaxy. Particularly advantageous are those layers which are realized additionally as tensile-strained layers.

Apart from InGaAs quantum films and with corresponding N-sources (hydrazine) and Sb-sources, InGaAsN, InGaAsSb, InGaAsNSb, GaAsN, AlAsN, GaAsSb, AlAsSb, GaAsP layers can be produced as quantum film structures and barrier structures on GaAs. Hereby, in particular in MOVPE, the following GaAs-based wavelengths are made accessible for disk lasers/VECSEL (VECSEL=Vertical External Cavity Surface Emitting laser):

| Quantum films: | Wavelengths: |
|---|---|
| InGaAs | <1,000 nm (standard sources) |
| InGaAs | <1,100 nm (TBAs, TBP) |
| InGaAsN | <1,300 nm/1500 nm (TBAs, TBP) |
| InGaAsNSb | <2,000 nm (TBAs, TBP, Sb sources) |

The design, depending on the wavelength, is particularly critical for efficient disk laser structures. With appropriate structures, the two (fundamental) wavelengths of 1,050 nm (frequency-doubled green) and 1,260 nm (frequency-doubled red) are able to be realized. These wavelengths, apart from the wavelengths known until now, reveal among others, the range of all the visible wavelengths by doubling of the resonator internal frequency.

During the epitaxy of disk lasers at an emission wavelength of 1,050 nm, an increased In-concentration can be realized at low growth temperatures of T<600° C. with the aforementioned TBAs sources for the InGaAs quantum films for the light production and TBP sources for the strain-compensating barrier layers in the active layer. At this wavelength, in general, no strain compensation of the high aluminum-containing layers which are particularly used in Bragg reflectors is required yet.

Particularly for disk lasers at longer wavelengths, a compensation of the strain of the Bragg mirror is, in general, advantageous at low growth temperatures for the different materials (typically AlAs-, GaAs-, or AlxGa1-xAs-layers with a varying Al proportion) with an abrupt change in the refractive index, since these material combinations already have different thermal expansion coefficients during the epitaxy and can lead to a material degradation.

For that purpose, different strain-compensating concepts exist, at which, particularly in the high aluminum-containing AlGaAs/AlAs layers, the slightly compressive strain can be tensilely compensated by the aluminum due to low concentrations of P. The barrier layers must be examined very critically depending on the optical absorption wavelengths and the concept of strain compensation for an efficient operation. Apart from GaAsP and AlGaAs layers, InGaAsN or GaAsN with absorption wavelengths >900 nm can also be produced according to the present invention as an absorption layer <900. In that, depending on the respective material combination, the sufficient confinement of charge carriers has to be respected in the conduction band and the valence band. Particularly for InGaAsN quantum films for the light production, sufficient confinement of holes by use of GaAsP/AlGaAs layers in the design is necessary for an efficient laser operation.

The procedure according to the current invention is particularly of a great advantage for disk laser variants for higher wavelengths. The production of such disk lasers is economically very relevant, due to the frequency doubling and corresponding color assignment, particularly in the area of 1,260 nm.

For the layer structures the installation of strain-compensating layers becomes more important with increasing emission wavelength and thus increasing strain. This compressive strain must be compensated by tensile-strained layers within the layer successions discussed here, which must contain active quantum film packages for an efficient absorption of the pump light in the range from e.g. 5 to 25 or more. For that purpose, either tensile-strained Ga(PAs) can be used in the active region, if a stimulation with a pump wavelength below 900 nm is desired, or tensile-strained Ga(Nas) or tensile-strained (GaIn)(Nas) respectively, if one would like to work with longer pump wavelengths. Due to the improved decomposition characteristics, these layer structures can be produced more precisely, in a more controlled manner, and with a greater lateral homogeneity.

Hereby, an individual quantum well package can consist of one but also of two quantum films.

The higher the emission wavelength becomes, the higher the layer thicknesses of the DBR structure (layer composition from lamda/4 layers) also have to become. Furthermore the difference of the refractive index between e.g. AlAs and GaAs becomes smaller with an increasing wavelength; this means that a higher number of DBR layer pairs must be deposited in order to achieve an identical reflection degree. As the integral elastic strain also increases for that structure with increasing layer thickness and number of DBR pairs, strain compensation must also be installed for the DBR part of the laser. To compensate the compressive strain of the (AlGa)As part, the strain can, on one hand, be reduced by addition of P— to this layer (DBR construction Al (high conc.) Ga(PAs)/(Al (small conc.) Ga)As). On the other hand, the compressive strain of the Al (high conc.) Ga)As can be compensated by tensile-strained Ga(PAs) or also by tensile-strained (Al (small conc.) Ga)(PAs).

Thus, the optically pumped semiconductor devices based on the current invention for the production of radiation feature respective tensile-strained or/and compression-strained semiconductor layers, which preferably have been produced by usage of the aforementioned TBAs sources or/and TBP sources in the commonly known epitaxy methods, in particular the MOVEPE methods.

1. Layer succession wherein the layer succession features one or several layers by use of TBAs sources and/or TBP sources by means of commonly known expitaxy methods.

2. Layer succession according to claim 1 wherein the at least one layer is realized as a strain-compensating layer for surrounding layer(s) of the semiconductor device.

3. Layer succession according to claim 1 wherein the one or several layers are arranged in the active region of the device.

4. Layer succession according to claim 1 wherein at least one of the layers is arranged in the area of the semiconductor layers realized as a reflector or one or multiple layer mirror.

5. Optically pumped semiconductor devices for the production of radiation wherein the semiconductor device features one or several of the layer successions according to claim 1.

6. Semiconductor device according to claim 5 wherein the device features at least one quantum well package which features one or two quantum films.

7. A method for the production of semiconductor layer structures wherein for the achievement of a strain control of one or several layers, TBAs sources or/and TBP sources, preferably tertiarybutylarsine (t-C4H9AsH2) or tertiarybutylphosphine (t-C4H9PH2, TBP) or sources featuring corresponding arsenic alkyl and alkylphosphine compounds, are used in the commonly known epitaxy methods.

8. Method according to claim 5 wherein MOVEPE or other deep temperature vapor phase expitaxy methods are used at a temperature of equal to or less than 600° C.

9. Use of TBAs sources or/and TBP sources, preferably tertiarybutylarsine (t-C4H9AsH2) or tertiarybutylphosphine (t-C4H9PH2, TBP) or corresponding arsenic alkyl and alkylphosphine compounds in expitaxy methods for the production of tension compensating semiconductor layers.

10. Use according to claim 9 wherein compression-strained semiconductor layers are compensated for their strain.

11. Layer succession according to claim 2 wherein the one or several layers are arranged in the active region of the device.

12. Layer succession according to claim 2 wherein at least one of the layers is arranged in the area of the semiconductor layers realized as a reflector or one or multiple layer mirror.

13. Layer succession according to claim 3 wherein at least one of the layers is arranged in the area of the semiconductor layers realized as a reflector or one or multiple layer mirror.

14. Optically pumped semiconductor devices for the production of radiation wherein the semiconductor device features one or several of the layer successions according to claim 2.

15. Optically pumped semiconductor devices for the production of radiation wherein the semiconductor device features one or several of the layer successions according to claim 3.

16. Optically pumped semiconductor devices for the production of radiation wherein the semiconductor device features one or several of the layer successions according to claim 4.
